(19) United States
(12) Patent Application Publication
(10) Pub. No.: US 2018/0174998 A1
(43) Pub. Date: Jun. 21, 2018

(54) METHOD FOR MANUFACTURING SEMICONDUCTOR DEVICE

(71) Applicant: TOYOTA JIDOSHA KABUSHIKI KAISHA, Toyota-shi (JP)

(72) Inventors: Kaisei SATO, Toyota-shi (JP); Keita HATASA, Nisshin-shi (JP); Tomomi OKUMURA, Kariya-shi (JP)

(73) Assignee: TOYOTA JIDOSHA KABUSHIKI KAISHA, Toyota-shi (JP)

(21) Appl. No.: 15/802,941

(22) Filed: Nov. 3, 2017

(30) Foreign Application Priority Data
Dec. 19, 2016 (JP) 2016-245623

(51) Int. Cl. H01L 23/00

(52) U.S. Cl. CPC H01L 24/85; H01L 24/27; H01L 24/32; H01L 2924/01029; H01L 24/91; H01L 2224/85205; H01L 2924/365; H01L 24/83

(57) ABSTRACT

Method for manufacturing a semiconductor device includes: preparing a first subassembly in which an upper surface of the conductive spacer is soldered on the second conductive member and preliminary solder is provided on a lower surface of the conductive spacer; preparing a second subassembly in which the lower surface of the semiconductor element is soldered on the first conductive member and the bonding wire is joined on upper surface of the semiconductor element; and soldering the upper surface of the semiconductor element in the second subassembly on the lower surface of the conducive spacer in the first subassembly by melting the preliminary solder in the first subassembly

### TECHNICAL FIELD

The present disclosure relates to a method for manufacturing a semiconductor device.

### BACKGROUND

Japanese Patent Application Publication No. 2004-303869 describes a semiconductor device and a method for manufacturing the same. The semiconductor device includes a semiconductor clement, a first conductive member joined on a lower surface of the semiconductor element, a second conductive member joined on an upper surface of the semiconductor element via a conductive spacer, and a bonding wire joined on the upper surface of the semiconductor element. The method for manufacturing the semiconductor device includes a first soldering step of soldering the conductive spacer on the first conductive member via the semiconductor element, a wire bonding step of joining the bonding wire on the semiconductor element, and a second soldering step of soldering the second conductive member onto the conductive spacer. At the second soldering step, a solder foil is placed between the conductive spacer and the second conductive member, and the solder foil is molten to thereby join the conductive spacer and the second conductive member to each other.

### SUMMARY

At the second soldering step described above, positions of three components, namely, the conductive spacer, the solder foil, and the second conductive member require to be aligned correctly. If the solder foil is placed displaced from a proper position, for example, the molten solder may be squeezed (overflown) out from between the conductive spacer and the second conductive member, thereby causing malfunctions such as a short circuit and a poor joint. However, simultaneous alignment of the three components is burdensome. A possible measure, therefore, is to weld the solder in advance onto the conductive spacer. Such solder is referred to as preliminary solder (or solder pre-coat). When the preliminary solder is provided on the conductive spacer, the second soldering step only requires alignment of the two components, namely, the conductive spacer and the second conductive member. A step of providing the preliminary solder can be incorporated in the first soldering step, and the second soldering step can thereby be facilitated and simplified.

With the preliminary solder provided on the conductive spacer, however, when the semiconductor element is heated at the wire bonding step, the preliminary solder on the conductive spacer may also be heated and oxidized. Oxidation of the preliminary solder leads to a poor joint at the subsequent second soldering step. In general, a semiconductor element does not require to be heated at the wire bonding step when an aluminum bonding wire is used. On the other hand, the semiconductor element requires to be heated when a copper bonding wire is used. The copper bonding wire, however, has advantages such as higher strength and superior electrical conductivity than the aluminum bonding wire does. In view of this, if the copper bonding wire is adopted, the copper bonding wire can be made thinner, thereby enabling miniaturization of the semiconductor element (especially, an electrode on the semiconductor element on which the bonding wire is to be joined). To adopt the copper bonding wire, however, the problem of oxidation of the preliminary solder, as mentioned above, needs to be solved.

The present teachings provides art that solves the problem of oxidation of preliminary solder, as mentioned above, and allows for adoption of a copper bonding wire.

The present teachings provides method for manufacturing a semiconductor device. The semiconductor device may comprise a semiconductor element, a first conductive member joined on a lower surface of the semiconductor element, a second conductive member joined on an upper surface of the semiconductor element via a conductive spacer, and a copper bonding wire joined on the upper surface of the semiconductor element, The method may comprise: preparing a first subassembly in which an upper surface of the conductive spacer is soldered on the second conductive member and preliminary solder is provided on a lower surface of the conductive spacer; preparing a second subassembly in which the lower surface of the semiconductor element is soldered on the first conductive member and the bonding wire is joined on the upper surface of the semiconductor element; and soldering the upper surface of the semiconductor element in the second subassembly on the lower surface of the conducive spacer in the first subassembly by melting the preliminary solder in the first subassembly.

In the manufacturing method described above, firstly, the first and second subassemblies are prepared separately. In the first subassembly, the upper surface of the conductive spacer is soldered on the second conductive member and the preliminary solder is provided on the lower surface of the conductive spacer. That is, the preliminary solder is provided in the first subassembly. In the second subassembly on the other hand, the lower surface of the semiconductor clement is soldered on the first conductive member and the bonding wire is joined on the upper surface of the semiconductor element. That is, the bonding wire is joined during a course of preparing the second subassembly. As such, by adopting the first subassembly in which the preliminary solder is provided and the second subassembly in which the bonding wire has already been joined, the preliminary solder in the first subassembly is not oxidized even when the semiconductor element is heated at the joining of the bonding wire. Subsequently, by melting the preliminary solder in the first subassembly, and soldering the upper surface of the semiconductor element in the second subassembly on the lower surface of the conductive spacer in the first subassembly, a configuration of the semiconductor device described above is completed.

Notably, the terms such as the upper surface and the lower surface in the present teachings are used, for sake of convenience, to represent surfaces disposed on opposite sides, and do not necessarily mean that the upper surface and the lower surface are disposed vertically above and vertically below, respectively. For example, in the process of manufacturing the semiconductor device, the upper surface of the semiconductor element may become a surface disposed on a lower side of the semiconductor element, and the lower surface of the semiconductor element may become a surface disposed on an upper side of the semiconductor element. The same applies to the upper and lower surfaces of the first and second conductive spacers and other members.

### BRIEF DESCRIPTION OF DRAWINGS

FIG. 1 is a cross-sectional view illustrating a structure of a semiconductor device

FIG. 2 is an enlarged vie a section II in FIG. 1.

FIG. 3 is a diagram illustrating a lower surface 26b of a conductive spacer 26.

FIG. 4 is a cross-sectional view taken along a line IV-IV in FIG. 3.

FIG. 5 is a flowchart illustrating a flow of an embodiment of a method for manufacturing the semiconductor device 10.

FIG. 6 illustrates steps S10 and S12 of preparing a first subassembly 10a.

FIG. 7 illustrates step S14 of soldering a semiconductor element 12 on a first conductive member 22, which step is a part of a step of preparing a second subassembly 10b.

FIG. 8 illustrates step S16 of joining a bonding wire 32 on the semiconductor element 12, which step is another part of the step of preparing the second subassembly 10b.

FIG. 9 illustrates step S18 of melting preliminary solder 44p to solder the first and second subassemblies 10a and 10b to each other.

FIG. 10 illustrates step S20 of packaging a third subassembly 10c with use of a sealing material 20m.

### DETAILED DESCRIPTION

In an embodiment of the present teachings, the conductive spacer may compose a concave portion formed along a peripheral edge of the lower surface of the conductive spacer. According to such a technique, when the preliminary solder is molten for soldering, excess solder is collected in the concave portion, thereby making it possible to prevent solder overflow.

In an embodiment of the present teachings, the preparing of the first subassembly may comprise soldering the conductive spacer on the second conductive member with the conductive spacer disposed vertically above the second conductive member. According to such a technique, the molten solder between the second conductive member and the conductive spacer becomes easy to be spread, under its own weight, on the second conductive member. The second conductive member therefore does not necessarily require a surface treatment for improving solder wettability (e.g., gold plating). Omitting such a surface treatment enables reduction of manufacturing costs of a semiconductor device.

In an embodiment of the present teachings, the preparing of the second subassembly may comprise soldering the lower surface of the semiconductor element on the first conductive member, and joining the bonding wire on the upper surface of the semiconductor element soldered on the first conductive member. According to such a technique, when the bonding wire is to be joined on the semiconductor element, as the semiconductor element has been fixed on the first conductive member, positioning of the semiconductor element along with the first conductive member is facilitated.

In au embodiment of the present teachings, the joining of the bonding wire may comprise heating the semiconductor element soldered on the first conductive member, and ultrasonic-joining the bonding wire on the upper surface of the heated semiconductor element. According to such a technique, a copper bonding wire can be joined on the semiconductor element with sufficient strength.

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved semiconductor device, as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

With reference to the drawings, description will be made of an embodiment of a method for manufacturing a semiconductor device 10. The semiconductor device 10 in the present embodiment can be used for applications including, but not particularly limited to, power conversion circuits such as a converter and an inverter in motor-driven vehicles such as a hybrid vehicle, a fuel-cell vehicle, or an electric vehicle, for example. In the following, a configuration of the semiconductor device 10 will initially be described, and then the method for manufacturing the semiconductor device 10 will be described. It should be noted, however, that the semiconductor device 10 and the method for manufacturing the same, described below, are an example, and a plurality of technological elements disclosed in the present teachings can be applied solely or in combinations to various semiconductor devices and methods for manufacturing the same.

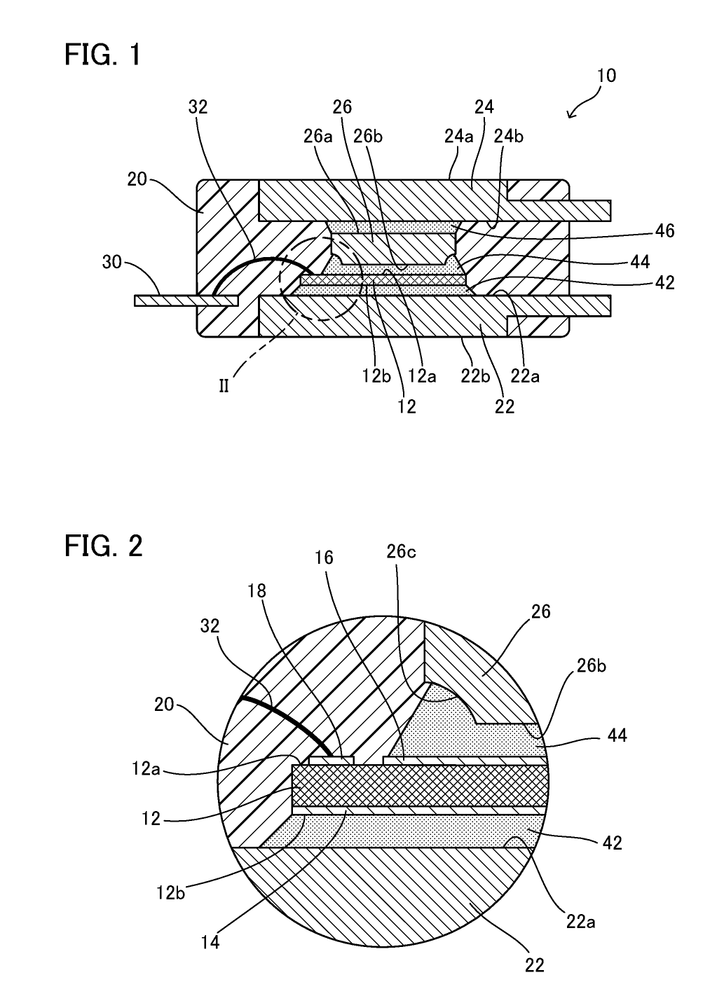

As shown in FIGS. 1 and 2, the semiconductor device 10 in the present embodiment includes a semiconductor element 12, and a sealing body 20 that seals the semiconductor element 12. The semiconductor element 12 is a power semiconductor element. A specific configuration of the semiconductor element 12 is not limited, but the semiconductor element 12 may be a switching element, a diode, or a combination thereof, for example. The switching element herein mentioned includes, for example, an IGBT (Insulated Gate Bipolar Transistor) or a MOSFET (Metal-Oxide-Semiconductor Field-Effect Transistor). A semiconductor material used for the semiconductor element 12 is not particularly limited, either, but may be silicon (Si), silicon carbide (SiC), or group III-V semiconductors, for example. The sealing body 20 is constituted of a material having insulating property. The sealing body 20 in the present embodiment is constituted of a material including, but not particularly limited to, a thermosetting resin material such as epoxy resin. Although FIG. 1 illustrates only one semiconductor element 12, two or more semiconductor elements 12 may be included in the semiconductor device 10.

The semiconductor element 12 includes a lower surface 12b on which a first electrode 14 is provided, and an upper surface 12a on which a second electrode 16 and a third electrode 18 are provided (see FIG. 2). The first and second electrodes 14 and 16 are electrodes for power supply; and the third electrode 18 is an electrode for signal. If the semiconductor element 12 is an IGBT, for example, the first electrode 14 may be an emitter electrode, and the second electrode 16 may be a collector electrode. If the semiconductor element 12 is a MOSFET, the first electrode 14 may be a source electrode, and the second electrode 16 may be a drain electrode. The third electrode 18 may be an electrode to which a control signal to the semiconductor element 12 (e.g., a gate drive signal) is inputted, or an electrode from which signals corresponding to a temperature and a current of the semiconductor element 12 are outputted.

The semiconductor device 10 further includes a first conductive member 22, a second conductive member 24, and a conductive spacer 26. The first conductive member 22 is constituted of a material having electrical conductivity, such as copper or other metals, for example. The first conductive member 22 takes a shape of a plate that has an upper surface 22a and a lower surface 22b. The upper surface 22a of the first conductive member 22 is joined on the lower surface 12b of the semiconductor element 12 inside the sealing body 20. More specifically, the first electrode 14 of the semiconductor element 12 is soldered on the first conductive member 22, and a first solder joint layer 42 is formed between the semiconductor element 12 and the first conductive member 22 (see FIG. 2). The first conductive member 22 is thereby electrically connected to the semiconductor element 12. The lower surface 22b of the first conductive member 22 is exposed to an outside of the sealing body 20. The first conductive member 22 is thermally connected as well to the semiconductor element 12, and also functions as a heat releasing member that releases heat of the semiconductor element 12 to an outside.

Each of the second conductive member 24 and the conductive spacer 26 is also constituted of a material having electrical conductivity, such as copper or other metals, for example. The second conductive member 24 takes a shape of a plate that has an upper surface 24a and a lower surface 24b. The conductive spacer 26 also takes a shape of a plate that has an upper surface 26a and a lower surface 26b. The lower surface 24b of the second conductive member 24 is joined on the upper surface 12a of the semiconductor element 12 via the conductive spacer 26, inside the sealing body 20. More specifically, the second electrode 16 of the semiconductor clement 12 is soldered on the lower surface 26b of the conductive spacer 26, and a second solder joint layer 44 is formed between the semiconductor element 12 and the conductive spacer 26 (see FIG. 2). The upper surface 26a of the conductive spacer 26 is soldered on the lower surface 24b of the second conductive member 24, and a third solder joint layer 46 is formed between the conductive spacer 26 and the second conductive member 24. The second conductive member 24 is thereby electrically connected to the semiconductor element 12 via the conductive spacer 26. The upper surface 24a of the second conductive member 24 is exposed to the outside of the sealing body 20. The second conductive member 24 is thermally connected as well to the semiconductor element 12 via the conductive spacer 26, and also functions as a heat releasing member that releases heat of the semiconductor element 12 to the outside.

The semiconductor device 10 further includes a third conductive member 30 and a bonding wire 32. The third conductive member 30 is constituted of a material having electrical conductivity, such as copper or other metals, for example. The third conductive member 30 extends from an inside to the outside of the sealing body 20. The bonding wire 32 electrically connects the third conductive member 30 and the semiconductor element 12 inside the sealing body 20, Specifically, one end of the bonding wire 32 is joined on the third conductive member 30 inside the sealing body 20, while the other end of the bonding wire 32 is joined on the third electrode 18 disposed on the upper surface 12a of the semiconductor element 12 (see FIG. 2). The third conductive member 30 is thereby electrically connected to the third electrode 18 of the semiconductor element 12 via the bonding wire 32.

The bonding wire 32 is a copper bonding wire. The copper bonding wire herein mentioned refers to a bonding wire that contains copper as a principal component, and may contain element(s) other than copper. In this case, a content rate of copper is not particularly limited, but may desirably be 95 mass percent or more. The copper bonding wire has advantages such as higher strength and superior electrical conductivity than an aluminum bonding wire does, for example. In view of this, if the bonding wire 32 thus made of copper is adopted, the bonding wire 32 can be made thinner. The bonding wire 32, thus made finer, enables downsizing of the third electrode 18 of the semiconductor element 12, thereby making it possible to miniaturize the semiconductor element 12. By the miniaturization of the semiconductor element 12, a large number of semiconductor elements 12 can be manufactured from a single semiconductor wafer, making it possible to reduce manufacturing costs of the semiconductor element 12 (i.e., manufacturing costs of the semiconductor devices 10).

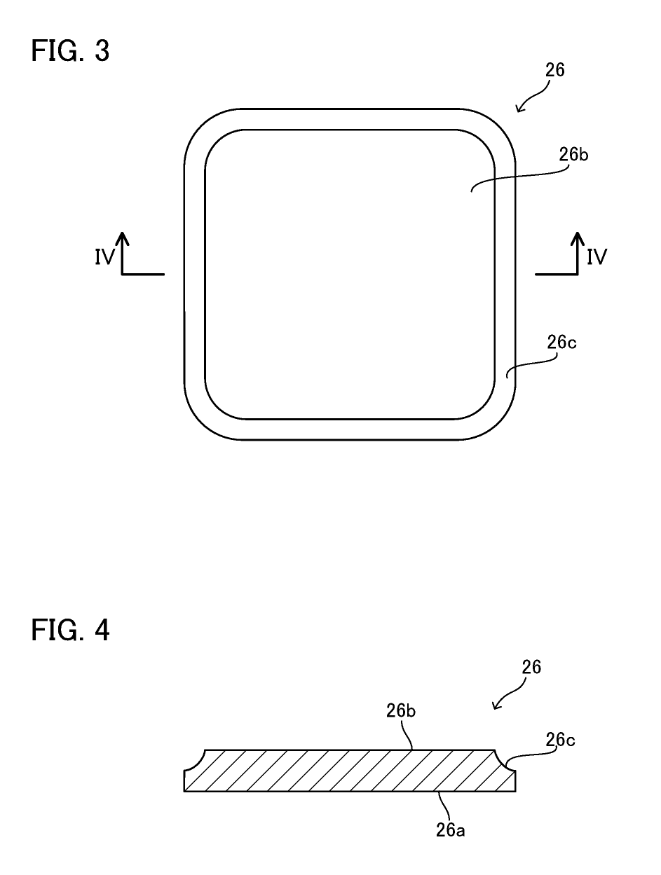

As shown in FIGS. 2-4, the conductive spacer 26 includes a concave portion 26c formed along a peripheral edge of the lower surface 26b. According to such a configuration, when the lower surface 26b of the conductive spacer 26 is soldered on the upper surface 12a of the semiconductor element 12, excess solder is collected in the concave portion 26c, thereby making it possible to prevent solder overflow. A specific structure of the concave portion 26c is not particularly limited, but the concave portion 26c in the present embodiment is delimited by a concavely-curved surface. The concave portion 26c may be formed continuously or discontinuously along the peripheral edge of the lower surface 26b. It should be noted that, as another embodiment, the conductive spacer 26 may not have the concave portion 26c.

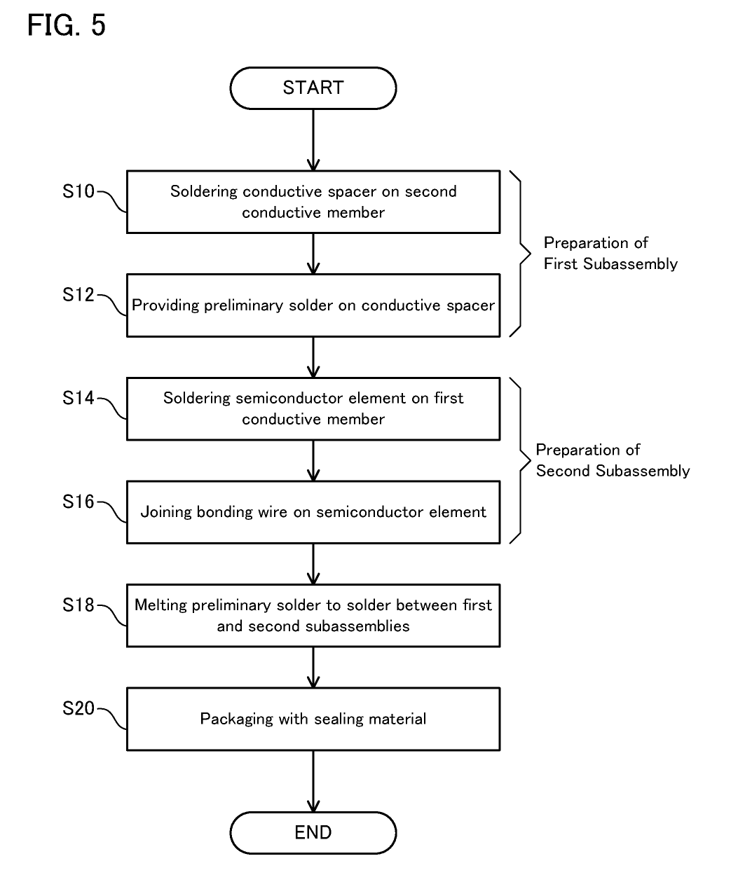

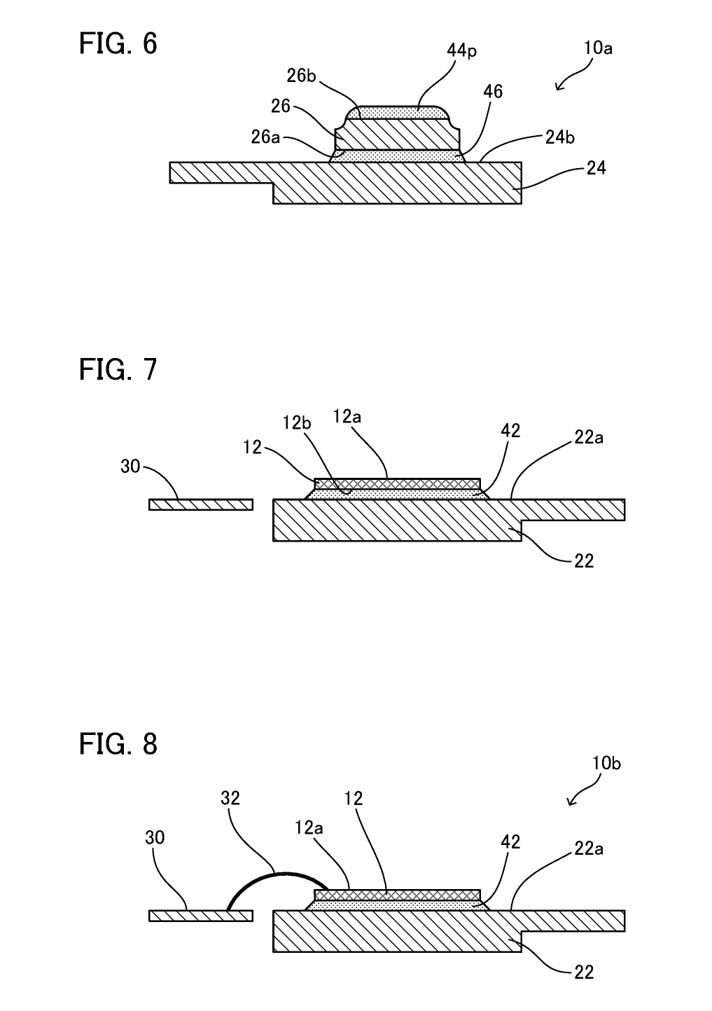

Next, a method for manufacturing the semiconductor device 10 will be described, FIG. 5 is a flowchart illustrating a flow of the manufacturing method. Along the flow of the manufacturing method shown in FIG. 5, each step will now be described in details hereinbelow. Firstly, at steps S10 and S12, a first subassembly 10a shown in FIG. 6 is prepared. In the first subassembly 10a, the upper surface 26a of the conductive spacer 26 is soldered on the lower surface 24b of the second conductive member 24, and preliminary solder 44p is provided on the lower surface 26b of the conductive spacer 26. Notably, when compared with FIG. 1, FIG. 6 illustrates the second conductive member 24 and the conductive spacer 26 upside down. Accordingly, in FIG. 6, the conductive spacer 26 has the upper surface 26a facing downward, and the lower surface 26b facing upward. The same applies to the second conductive member 24.

A specific technique for preparing the first subassembly 10a is not particularly limited. As an example in the present embodiment, the upper surface 26a of the conductive spacer 26 is soldered, at step S 10, on the lower surface 24b of the second conductive member 24. As shown in FIG. 6, this soldering can be performed with the conductive spacer 26 disposed vertically above the second conductive member 24. According to such a technique, the molten solder between the second conductive member 24 and the conductive spacer 26 (i.e., the solder which forms the third solder joint layer 46) is made easier to spread, under its own weight, on the second conductive member 24. The second conductive member 24 therefore does not necessarily require a surface treatment for improving solder' wettability (e.g., gold plating). Omitting such a surface treatment enables reduction of manufacturing costs of the semiconductor device 10.

At step S12, the preliminary solder 44p is provided on the lower surface 26b of the conductive spacer 26. That is, the solder is temporarily molten on the lower surface 26b of the conductive spacer 26, and adhered on the lower surface 26b. The preliminary solder 44p becomes the second solder joint layer 44 at the subsequent step. Here, steps S10 and S12 may be performed in any order, and either step may be performed first. Alternatively; both steps S10 and S12 may simultaneously be performed partially or wholly.

Next, at steps S14 and S16, a second subassembly 10b shown in FIG. 8 is prepared. In the second subassembly 10b, the lower surface 12b of the semiconductor element 12 is soldered on the upper surface 22a of the first conductive member 22, and the bonding wire 32 is joined on the upper surface 12a of the semiconductor element 12. Notably, steps S14 and 516 of preparing the second subassembly 10b may be performed earlier than, or performed in parallel with, steps S10 and S12 of preparing the first subassembly 10a.

A specific technique for preparing the second subassembly 10b is not particularly limited. As an example in the present embodiment, as shown in FIG. 7, the lower surface 12b of the semiconductor element 12 is soldered, at step S14, on the upper surface 22a of the first conductive member 22. Next, as shown in FIG. 8, the bonding wire 32 is joined, at step S16, on the upper surface 12a of the semiconductor element 12 and the third conductive member 30. Steps S14 and S16 may be performed in any order. It should be noted, however, that performing step S16 after step S14 facilitates positioning of the semiconductor element 12 along with the first conductive member 22 because, when the bonding wire 32 is to be joined on the semiconductor element 12, the semiconductor element 12 has already been fixed to the first conductive member 22.

At step S16 of joining the bonding wire 32, the semiconductor eluent 12 soldered on the first conductive member 22 is heated, and the bonding wire 32 can be ultrasonic-joined on the upper surface 12a of the heated semiconductor element 12. That is, the bonding wire 32 made to abut against the upper surface 12a of the semiconductor element 12 can be vibrated ultrasonically. According to such a technique, the bonding wire 32 made of copper can be joined on the semiconductor element 12 with sufficient strength. A technique for heating the semiconductor element 12 is not particularly limited. For example, the semiconductor element 12 can be heated via the first conductive member 22 by placing the first conductive member 22 on a heater (not shown). A target temperature to which the semiconductor element 12 is heated may be set to 180° C. or higher, for example, in the present embodiment, an amount of heating by the heater is not particularly limited, but is adjusted such that the upper surface 12a of the semiconductor element 12 reaches 200° C.

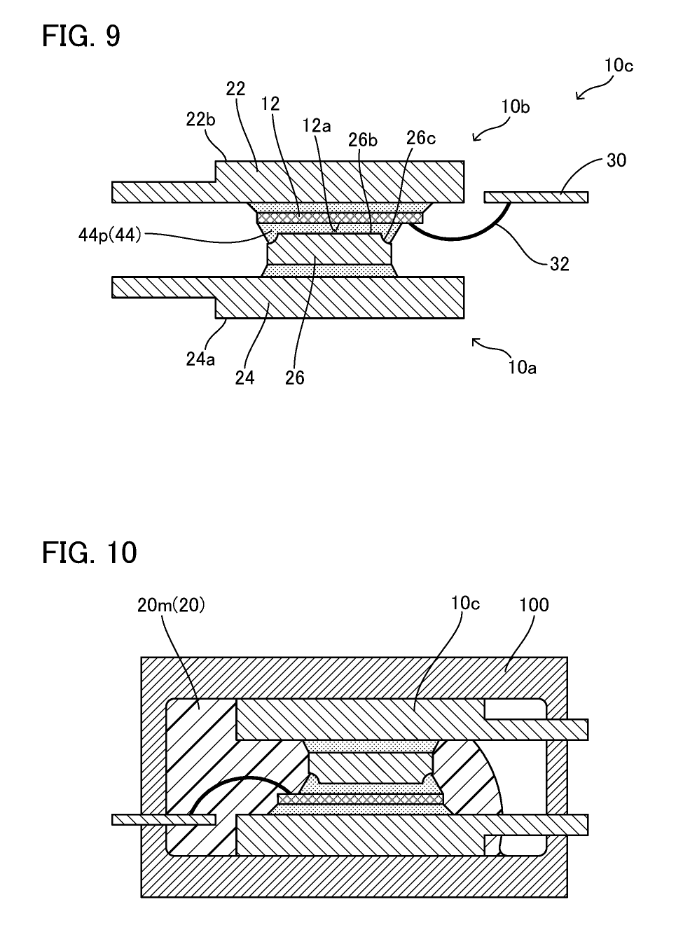

With steps S10-S16 described above, the first and second subassemblies 10a and 10b are prepared separately. Next, at step S18 in FIG. 5, the preliminary solder 44p in the first subassembly 10a is molten, and the first and second subassemblies 10a and 10b are soldered to each other. Specifically, the upper surface 12a of the semiconductor element 12 in the second subassembly 10b is soldered on the lower surface 26b of the conductive spacer 26 in the first subassembly 10a. A third subassembly 10c shown in FIG. 9 is thereby prepared. As shown in FIG. 9, at step S18 of soldering with use of the preliminary solder 44p, the first subassembly 10a on which the preliminary solder 44p is provided can be placed vertically below the second subassembly 10b. Notably, when compared with FIG. 1, FIG. 9 illustrates all the members upside down.

At step S18 of soldering with use of the preliminary solder 44p, relative position between the first and second subassemblies 10a and 10b is adjusted such that a distance from the lower surface 22b of the first conductive member 22 to the upper surface 24a of the second conductive member 24 is equal to a design value. By doing so, the distance between the upper surface 12a of the semiconductor element 12 and the lower surface 26b of the conductive spacer 26 may be in some cases smaller than the design value, in accordance with actual dimensions of the first and second subassemblies 10a and 10b. In this case, a part of the molten preliminary solder 44p becomes excess, however, the excess solder is collected in the concave portion 26c of the conductive spacer 26, thereby making it possible to prevent the molten preliminary solder 44p from overflowing.

Next, at step S20 in FIG. 5, packaging is performed with use of a sealing material 20m. As shown in FIG. 10, the packaging with use of the sealing material 20m can be performed by insert molding, That is, the third subassembly 10c is placed in a mold 100, into which the sealing material 20m is injected. The sealing material 20m that fills the mold 100 is cured as the temperature decreases, and turns into the sealing body 20 of the semiconductor device 10 (see FIG. 1). Subsequently, the third subassembly 10c thus packaged is removed from the mold 100, is subjected to necessary finish treatment, and the semiconductor device 10 is thereby completed.

As described above, in the manufacturing method in the present embodiment, firstly, the first and second subassemblies 10a and 10b are prepared separately. In the first subassembly 10a, the upper surface 26a of the conductive spacer 26 is soldered on the second conductive member 24 and the preliminary solder 44p is provided on the lower surface 26b of the conductive spacer 26. In the second subassembly 10b on the other hand, the lower surface 12b of the semiconductor element 12 is soldered on the first conductive member 22 and the bonding wire 32 is joined on the upper surface 12a of the semiconductor element 12. That is, the joining of the bonding wire 32 is performed during a course of preparing the second subassembly 10b, and does not affect the preliminary solder 44p in the first subassembly 10a, As such, by adopting the first subassembly 10a in which the preliminary solder 44p has been already provided, and the second subassembly 10b in which the bonding wire 32 has already been joined, the preliminary solder 44p is not oxidized even when the semiconductor element 12 is heated at the joining of the bonding wire 32. A copper bonding wire can therefore be adopted as the bonding wire 32. As mentioned above, adopting the bonding wire 32 made of copper enables miniaturization of the semiconductor element 12, making it possible to reduce manufacturing costs of the semiconductor element 12 (i.e., manufacturing costs of the semiconductor device 10).

What is claimed is:

1. Method for manufacturing a semiconductor device which comprises a semiconductor element, a first conductive member joined on a lower surface of the semiconductor element, a second conductive member joined on an upper surface of the semiconductor element via a conductive spacer, and a copper bonding wire joined on the upper surface of the semiconductor element, the method comprising:
preparing a first subassembly in which an upper surface of the conductive spacer is soldered on the second conductive member and preliminary solder is provided on a lower surface of the conductive spacer;
preparing a second subassembly in which the lower surface of the semiconductor element is soldered on the first conductive member and the bonding wire is joined on the upper surface of the semiconductor element; and
soldering the upper surface of the semiconductor element in the second subassembly on the lower surface of the conducive spacer in the first subassembly by melting the preliminary solder in the first subassembly.

2. The method according to claim 1, wherein the conductive spacer comprises a concave portion formed along a peripheral edge of the lower surface of the conductive spacer.

3. The method according to claim 1, wherein the preparing of the first subassembly comprises soldering the conductive spacer on the second conductive member with the conductive spacer disposed vertically above the second conductive member.

4. The method according to claim 1, wherein the preparing of the second subassembly comprises: soldering the lower surface of the semiconductor element on the first conductive member; and joining the bonding wire on the upper surface of the semiconductor element soldered on the first conductive member.

5. The method according to claim 4, wherein the joining of the bonding wire comprises: heating the semiconductor element soldered on the first conductive member; and ultrasonic-joining the bonding wire on the upper surface of the heated semiconductor element.
